(19) United States
(12) Patent Application Publication
(10) Pub. No.: US 2026/0130067 A1
(43) Pub. Date: May 7, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventors: Yun Mo CHUNG, Yongin-si (KR); Dae Woo LEE, Yongin-si (KR); Woo Sik JUN, Yongin-si (KR)

(21) Appl. No.: 19/280,999

(22) Filed: Jul. 25, 2025

(30) Foreign Application Priority Data
Nov. 5, 2024 (KR) 10-2024-0155264

(51) Int. Cl. H10K 59/127; H10K 59/122; H10K 59/131; H10K 59/38; H10K 59/80; H10K 59/88; H10K 102/00

(52) U.S. Cl. CPC H10K 59/127; H10K 59/131; H10K 59/38; H10K 59/8731; H10K 59/88; H10K 59/122; H10K 2102/351

(57) ABSTRACT

Provided a display device which includes a first substrate; a second substrate; a sealing layer; and spacers supporting a gap between the first substrate and the second substrate. The first substrate includes a first support substrate and an element layer including light emitting elements disposed in emission areas. The second substrate includes a second support substrate and a color conversion layer. The color conversion layer includes main conversion portions respectively overlapping the emission areas and having a first thickness; dummy conversion portions arranged side by side with each other in a partial area of a non-display area in contact with a display area; and a partition wall disposed between the main 10 conversion portions and the dummy conversion portions. Each of at least some dummy conversion portions among the dummy conversion portions has a second thickness greater than the first thickness.

This application claims priority to Korean Patent Application No. 10-2024-0155264, filed on Nov. 5, 2024, and all the benefits accruing therefrom under 35 U.S.C. § 119, the content of which in its entirety is herein incorporated by reference.

### BACKGROUND

### 1. Field

The present disclosure relates to a display device and an electronic device including the display device.

### 2. Description of the Related Art

With the advance of information-oriented society, the demand is increasing for display devices capable of displaying images in various ways. For example, display devices are employed in various electronic devices such as, for example, smartphones, digital cameras, laptop computers, navigation devices, and smart televisions.

The display devices may be a flat panel display device such as, for example, a liquid crystal display device, a field emission display device and a light emitting display device. Examples of the light emitting display device may include an organic light emitting display device including organic light emitting elements, an inorganic light emitting display device including inorganic light emitting elements such as, for example, inorganic semiconductors, and a micro light emitting display device including micro light emitting elements.

An organic light emitting display device displays an image using light emitting elements, each including a light emitting layer formed of an organic light emitting material. As described herein, the organic light emitting display device implements image display using a self-light emitting element, and thus may have relatively superior performance in power consumption, response speed, luminous efficiency, luminance, and wide viewing angle compared to other display devices.

In some display devices, a display surface from which light is emitted may include a display area in which an image is displayed, and a non-display area around the display area. Emission areas emitting light with respective luminances and colors may be arranged in the display area.

### SUMMARY

The display device may include a first substrate and a second substrate facing each other, and a sealing layer which bonds the first substrate and the second substrate.

The first substrate may include light emitting elements disposed in the emission areas arranged in the display area, and may emit light from the emission areas at respective luminances.

The second substrate may selectively emit the light from the emission areas emitted from the first substrate to the outside.

The display device may further include spacers that support a gap between the first substrate and the second substrate.

The spacers may be arranged to be spaced apart from each other in the display area and the non-display area.

To improve the reliability of adhesion between each of the first substrate and the second substrate and the sealing layer, physical pressure for bonding the first substrate and the second substrate may be relatively strongly applied partially to the non-display area overlapping or adjacent to the sealing layer.

As a result, a pressing defect of the spacers arranged in the non-display area may easily be induced. In some cases, the pressing defect of the spacers may easily cause defects such as, for example, cracks or breakage to an inorganic insulating material of an encapsulation layer, and the cracked or broken inorganic insulating material may be a permeation path for oxygen or moisture. Accordingly, the display quality and lifespan of the display device may be deteriorated.

In view of the foregoing, aspects of the present disclosure provide a display device and an electronic device including the same, capable of improving the display quality and lifespan of the display device and the electronic device by reducing the pressing defect of spacers due to physical pressure applied when a first substrate and a second substrate are bonded.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a first substrate and a second substrate facing each other; a sealing layer which bonds the first substrate and the second substrate; and spacers supporting a gap between the first substrate and the second substrate. The first substrate includes a first support substrate including a display area including emission areas arranged side by side with each other, and a non-display area surrounding the display area; and an element layer including light emitting elements disposed in the emission areas on the first support substrate. The second substrate includes a second support substrate including the display area and the non-display area; and a color conversion layer disposed on a surface of the second support substrate facing the first support substrate. The color conversion layer includes main conversion portions respectively overlapping the emission areas and having a first thickness; dummy conversion portions arranged side by side with each other in a partial area of the non-display area in contact with the display area; and a partition wall disposed between the main conversion portions and the dummy conversion portions. Each of at least some dummy conversion portions among the dummy conversion portions has a second thickness greater than the first thickness.

The element layer includes a power supply auxiliary line disposed in the non-display area and overlapping the dummy conversion portions; through holes formed in the power supply auxiliary line and arranged side by side with each other; and hole cap portions covering the through holes and spaced apart from each other. The spacers overlap the partition wall. At least one spacer, which overlaps the partition wall between the dummy conversion portions among the spacers, overlaps at least one of the hole cap portions.

The first substrate further includes a circuit layer disposed on the first support substrate; and an encapsulation layer covering the element layer. The element layer is disposed on the circuit layer. The element layer includes first light emitting electrodes disposed in the emission areas on the circuit layer; a pixel defining layer which is disposed on the circuit layer, overlaps a non-emission area between the emission areas, and covers an edge of each of the first light emitting electrodes; a light emitting layer disposed on the first light emitting electrodes; and a second light emitting electrode disposed on the light emitting layer. Each of the light emitting elements has a structure in which the light emitting layer is sandwiched between a respective first light emitting electrode and the second light emitting electrode. The power supply auxiliary line is disposed in a same layer as the first light emitting electrodes. The hole cap portions are disposed in a same layer as the pixel defining layer.

The encapsulation layer includes a first encapsulation layer disposed on the second light emitting electrode and includes an inorganic insulating material; a second encapsulation layer disposed on the first encapsulation layer, overlapping the display area, and including an organic insulating material; and a third encapsulation layer covering the second encapsulation layer and including the inorganic insulating material. The spacers are in contact with the third encapsulation layer.

The circuit layer includes light emitting pixel drivers electrically connected to the first light emitting electrodes; and a power supply line disposed in the non-display area. The power supply line is electrically connected to the second light emitting electrode and the power supply auxiliary line.

One or more dummy conversion portions among the dummy conversion portions are adjacent to corners of the second substrate and have the second thickness. One or more remaining dummy conversion portions among the dummy conversion portions have the first thickness.

The dummy conversion portions have the second thickness.

A difference between the first thickness and the second thickness is about 0.5 μm or more.

The emission areas include a first emission area which emits light of a first wavelength band; a second emission area which emits light of a second wavelength band that is lower than the first wavelength band; and a third emission area which emits light of a third wavelength band that is lower than the second wavelength band. The light emitting elements emit light of a fourth wavelength band that is equal to or lower than the third wavelength band. The main conversion portions include a first color conversion portion which overlaps the first emission area and converts light of the fourth wavelength band into light of the first wavelength band; a second color conversion portion which overlaps the second emission area and converts light of the fourth wavelength band into light of the second wavelength band; and a light transmitting portion which overlaps the third emission area and transmits light of the fourth wavelength band.

Among the at least some dummy conversion portions, a width of a first dummy conversion portion replacing the first color conversion portion is equal to a width of the first color conversion portion. Among the at least some dummy conversion portions, a width of a second dummy conversion portion replacing the second color conversion portion is equal to a width of the second color conversion portion. Among the at least some dummy conversion portions, a width of a third dummy conversion portion replacing the light transmitting portion is equal to a width of the light transmitting portion.

Among the at least some dummy conversion portions, a width of a first dummy conversion portion replacing the first color conversion portion is smaller than a width of the first color conversion portion. Among the at least some dummy conversion portions, a width of a second dummy conversion portion replacing the second color conversion portion is smaller than a width of the second color conversion portion. Among the at least some dummy conversion portions, a width of a third dummy conversion portion replacing the light transmitting portion is smaller than a width of the light transmitting portion.

The second substrate further includes a color filter layer disposed on a surface of the second support substrate; and a filter capping layer covering the color filter layer. The color conversion layer is disposed on the filter capping layer. The color filter layer includes a first filter portion which overlaps the first emission area and transmits light of the first wavelength band; a second filter portion which overlaps the second emission area and transmits light of the second wavelength band; a third filter portion which overlaps the third emission area and transmits light of the third wavelength band; and a light blocking portion disposed between the first filter portion, the second filter portion, and the third filter portion.

According to an aspect of the present disclosure, there is provided an electronic device includes a display device displaying an image. The display device includes a first substrate and a second substrate facing each other; a sealing layer which bonds the first substrate and the second substrate; and spacers supporting a gap between the first substrate and the second substrate. The first substrate includes a first support substrate including a display area including emission areas arranged side by side with each other, and a non-display area surrounding the display area; and a circuit layer disposed on the first support substrate; an element layer including light emitting elements disposed in the emission areas on the circuit layer. An encapsulation layer covering the element layer. The second substrate includes a second support substrate including the display area and the non-display area; a color conversion layer disposed on a surface of the second support substrate facing the first support substrate; a filter capping layer covering the color filter layer; a color conversion layer disposed on the filter capping layer; and a color conversion capping layer covering the color conversion layer. The color conversion layer includes main conversion portions respectively overlapping the emission areas and having a first thickness; dummy conversion portions arranged side by side with each other in a partial area of the non-display area in contact with the display area; and a partition wall disposed between the main conversion portions and the dummy conversion portions. Each of at least some dummy conversion portions among the dummy conversion portions has a second thickness greater than the first thickness.

The element layer includes first light emitting electrodes disposed in the emission areas on the circuit layer; a pixel defining layer which is disposed on the circuit layer, overlaps a non-emission area between the emission areas, and covers an edge of each of the first light emitting electrodes; a light emitting layer disposed on the first light emitting electrodes; a second light emitting electrode disposed on the light emitting layer; a power supply auxiliary line disposed in the non-display area on the circuit layer and overlapping the dummy conversion portions; through holes formed in the power supply auxiliary line and arranged side by side with each other; and hole cap portions which are disposed in a same layer as the pixel defining layer, cover the through holes, and are spaced apart from each other. Each of the light emitting elements has a structure in which the light emitting layer is sandwiched between a respective first light emitting electrode and the second light emitting electrode. The spacers overlap the partition wall. At least one spacer, which overlaps the partition wall between the dummy conversion portions among the spacers, overlaps at least one of the hole cap portions.

The encapsulation layer includes a first encapsulation layer disposed on the second light emitting electrode and including an inorganic insulating material; a second encapsulation layer disposed on the first encapsulation layer, overlapping the display area, and including an organic insulating material; and a third encapsulation layer covering the second encapsulation layer and including the inorganic insulating material. The spacers are in contact with the third encapsulation layer.

One or more dummy conversion portions among the dummy conversion portions are adjacent to corners of the second substrate and have the second thickness. One or more remaining dummy conversion portions among the dummy conversion portions have the first thickness.

The dummy conversion portions have the second thickness.

The emission areas include a first emission area which emits light of a first wavelength band; a second emission area which emits light of a second wavelength band that is lower than the first wavelength band; and a third emission area which emits light of a third wavelength band that is lower than the second wavelength band. The light emitting elements emit light of a fourth wavelength band that is equal to or lower than the third wavelength band. The main conversion portions include a first color conversion portion which overlaps the first emission area and converts light of the fourth wavelength band into light of the first wavelength band; a second color conversion portion which overlaps the second emission area and converts light of the fourth wavelength band into light of the second wavelength band; and a light transmitting portion which overlaps the third emission area and transmits light of the fourth wavelength band.

Among the at least some dummy conversion portions, a width of a first dummy conversion portion replacing the first color conversion portion is equal to a width of the first color conversion portion. Among the at least some dummy conversion portions, a width of a second dummy conversion portion replacing the second color conversion portion is equal to a width of the second color conversion portion. Among the at least some dummy conversion portions, a width of a third dummy conversion portion replacing the light transmitting portion is equal to a width of the light transmitting portion.

Among the at least some dummy conversion portions, a width of a first dummy conversion portion replacing the first color conversion portion is smaller than a width of the first color conversion portion. Among the at least some dummy conversion portions, a width of a second dummy conversion portion replacing the second color conversion portion is smaller than a width of the second color conversion portion. Among the at least some dummy conversion portions, a width of a third dummy conversion portion replacing the light transmitting portion is smaller than a width of the light transmitting portion.

The display device according to embodiments may include a first substrate and a second substrate facing each other, a sealing layer bonding between the first substrate and the second substrate, and spacers supporting a gap between the first substrate and the second substrate.

The first substrate may include a first support substrate, the second substrate may include a second support substrate, and each of the first support substrate and the second support substrate may include a display area in which emission area are arranged and a non-display area surrounding the display area.

The second substrate may include main conversion portions overlapping the emission areas and disposed with a first thickness, dummy conversion portions arranged side by side with each other in a partial area of the non-display area in contact with the display area, and a partition wall disposed between the main conversion portions and the dummy conversion portions.

According to the embodiments, each of at least some dummy conversion portions among the dummy conversion portions may have a second thickness greater than the first thickness.

In this way, although the physical pressure for bonding the first substrate and the second substrate is relatively strongly applied to at least a portion of the non-display area overlapping a sealing layer, the physical pressure may be distributed to dummy conversion portions having a second thickness together with the spacers. Accordingly, the pressing defect associated with the spacers may be reduced, and thus the breakage or cracks of an inorganic insulating material of an encapsulation layer may be prevented or mitigated.

Accordingly, the defect of oxygen or moisture permeating into light emitting elements through the cracked or broken inorganic insulating materials may be prevented or reduced, such that the display quality and lifespan of the display device may be improved.

It should be noted that effects of the present disclosure are not limited to those described herein and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to an embodiment;

FIG. 2 is a cross-sectional view taken along line A-A′ of FIG. 1;

FIG. 3 is a schematic diagram illustrating a display area and a circuit layer of part B illustrated in FIG. 1;

FIG. 4 is a block diagram illustrating the circuit layer of part D illustrated in FIG. 3;

FIG. 5 is an equivalent circuit diagram illustrating the light emitting pixel driver of FIG. 4;

FIG. 6 is a cross-sectional view taken along line E-E′ of FIG. 3;

FIG. 7 is a schematic diagram illustrating a color conversion layer, spacers, and a power supply auxiliary line of part C illustrated in FIG. 1;

FIGS. 8, 9, 10 and 11 are cross-sectional views taken along lines F-F′, G-G′, H-H′ and I-I′ of FIG. 7 according to an embodiment;

FIG. 12 is a cross-sectional view taken along line F-F′ of FIG. 7 when a pressure for bonding the first substrate and the second substrate is concentrated;

FIGS. 13 and 14 are cross-sectional views taken along lines H-H′ and I-I′ of FIG. 7 according to an embodiment;

FIGS. 15 and 16 are cross-sectional views taken along lines F-F′ and G-G′ of FIG. 7 according to an embodiment;

FIG. 17 is a block diagram illustrating an electronic device according to an embodiment; and

FIG. 18 is a schematic diagram of electronic devices according to embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. The term “overlap” may include layer, stack, face or facing, extending over, covering, or partly covering or any other suitable term as would be appreciated and understood by those of ordinary skill in the art. The expression “not overlap” may include meaning such as, for example, “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently based on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. In an example in which “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

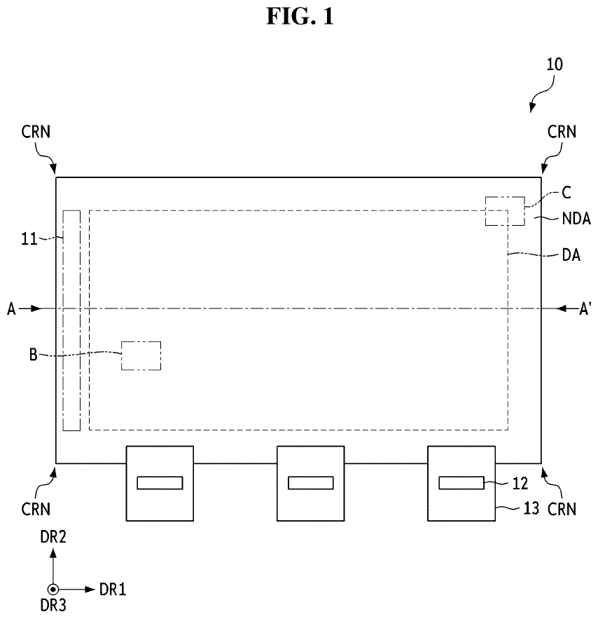

FIG. 1 is a plan view illustrating a display device according to an embodiment.

Referring to FIG. 1, a display device 10 according to an embodiment, which is a device for displaying a moving image or a still image, may be used as a display screen of various electronic devices, such as, for example, a television, a laptop computer, a monitor, a billboard and an Internet-of-Things (IOT) device, as well as portable electronic devices such as, for example, a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as, for example, an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 10 is an organic light emitting display device. However, embodiments of the present disclosure are not limited thereto, and may be applied to a display device including an organic insulating material, an organic light emitting material, and a metal material.

The display device 10 may be formed to be flat, but is not limited thereto. For example, the display device 10 may include a curved portion formed at left and right ends and having a constant curvature or a varying curvature. In some aspects, the display device may be formed flexibly such that the display device 10 can be curved, bent, folded, or rolled.

According to an embodiment, the display device 10 may be an organic light emitting display device.

As illustrated in FIG. 1, the display device 10 according to embodiments may include one surface of a quadrangle. However, this is an example, and the shape of the display device is not limited to that illustrated in FIG. 1. That is, the display device 10 according to embodiments may include one surface of a circle or a polygon other than a quadrangle. Alternatively, at least a part of the display device 10 may be unfolded, and transformed to be bent, curved, folded, or rolled.

One surface of the display device 10 may include a display area DA that emits light for displaying an image, and a non-display area NDA surrounding the display area DA.

The display area DA may be disposed in most of one surface of the display device 10.

The non-display area NDA may not emit light for displaying an image, and may have a frame shape that surrounds the periphery of the display area DA. For example, the non-display area NDA may be maintained in a specific color such as, for example, black or the like.

One surface of the display device 10 may include corners CRN at which edges in crossing directions meet. In an example in which one surface of the display device 10 is quadrilateral, the display device 10 may include the four corners CRN.

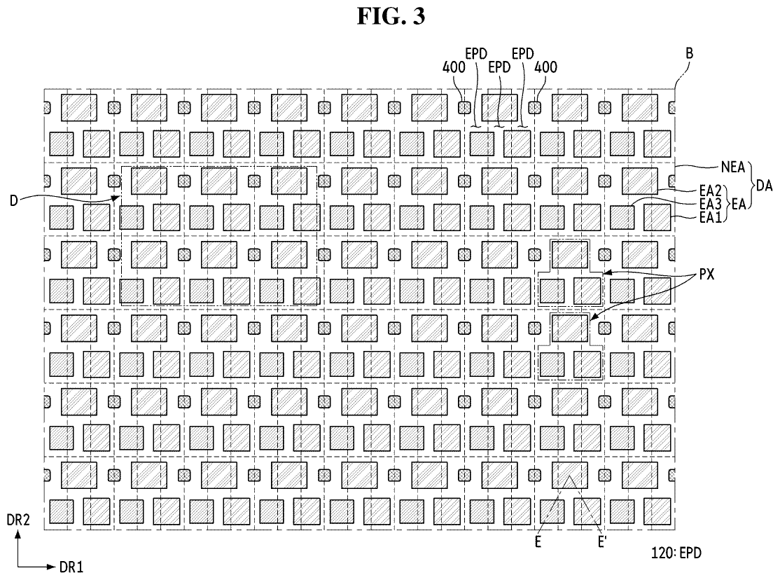

The display device 10 may include drivers 11 and 12 that transmit signals, voltage, or power to light emitting pixel drivers EPD (see FIGS. 3, 4, and 5) disposed in the display area DA.

The driver 11, which is a part of the drivers 11 and 12, may be implemented as a relatively simple circuit, and may be disposed in the non-display area NDA.

The driver 12, which is the other part of the drivers 11 and 12, may be provided as an integrated circuit chip, and may be mounted on a circuit board 13 electrically connected to pads of the non-display area NDA. Alternatively, the other driver 12 may be mounted on the pads of the non-display area NDA.

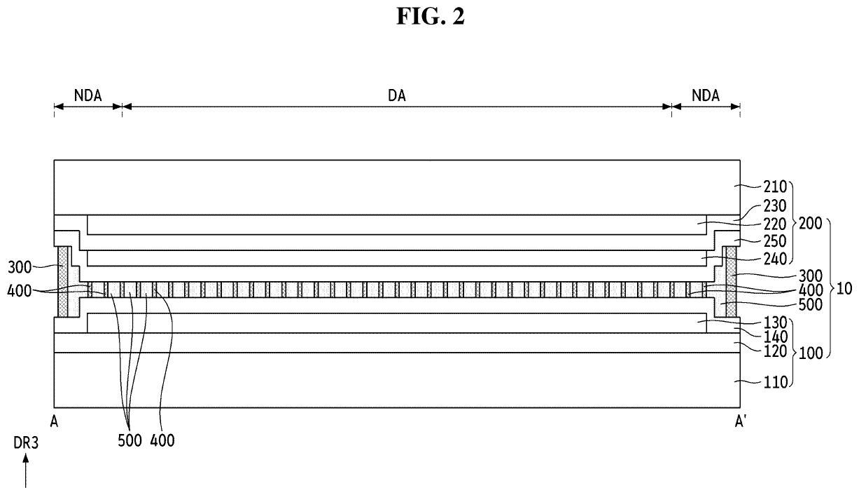

FIG. 2 is a cross-sectional view taken along line A-A′ of FIG. 1.

Referring to FIG. 2, the display device 10 according to an embodiment may include a first substrate 100 and a second substrate 200 that face each other, a sealing layer 300 that bonds the first substrate 100 and the second substrate 200, and spacers 400 that support a gap between the first substrate 100 and the second substrate 200.

The display device 10 according to an embodiment may further include a filling layer 500 that fills a space surrounded by the first substrate 100, the second substrate 200, and the sealing layer 300.

Each of the first substrate 100 and the second substrate 200 may include the display area DA from which light is emitted for displaying an image and the non-display area NDA disposed around the display area DA and from which light is not emitted.

According to an embodiment, the first substrate 100 may include a first support substrate 110 including the display area DA and the non-display area NDA, and an element layer 130 disposed on the first support substrate 110.

The first substrate 100 may further include a circuit layer 120 disposed on the first support substrate 110 and an encapsulation layer 140 covering the element layer 130. The element layer 130 may be disposed on the circuit layer 120.

That is, according to an embodiment, the first substrate 100 may include the first support substrate 110, the circuit layer 120 disposed on the first support substrate 110, the element layer 130 disposed on the circuit layer 120, and the encapsulation layer 140 disposed on the element layer 130.

According to an embodiment, the second substrate 200 may include a second support substrate 210 including the display area DA and the non-display area NDA, and a color conversion layer 240 disposed on a surface of the second support substrate 210 facing the first support substrate 110.

The second substrate 200 may further include a color filter layer 220 disposed on a surface of the second support substrate 210, and a filter capping layer 230 covering the color filter layer 220.

The color conversion layer 240 may be disposed on the filter capping layer 230.

The second substrate 200 may further include a color conversion capping layer 250 covering the color conversion layer 240.

That is, according to an embodiment, the second substrate 200 may include the second support substrate 210, the color filter layer 220 disposed on a surface of the second support substrate 210, the filter capping layer 230 disposed on the color filter layer 220, the color conversion layer 240 disposed on the filter capping layer 230, and the color conversion capping layer 250 disposed on the color conversion layer 240.

According to an embodiment, each of the filter capping layer 230 and the color conversion capping layer 250 may include an inorganic insulating material.

The sealing layer 300 may be disposed in the non-display area NDA between the first substrate 100 and the second substrate 200.

The spacers 400 are disposed in the display area DA and the non-display area NDA and may be spaced apart from each other.

According to an embodiment, the spacers 400 may be arranged regularly.

FIG. 3 is a schematic diagram illustrating a display area and a circuit layer of part B illustrated in FIG. 1.

Referring to FIG. 3, the display area DA may include emission areas EA that emit light at respective luminances, and a non-emission area NEA disposed between the emission areas EA.

According to an embodiment, the emission areas EA may include a first emission area EA1 that emits light of a first wavelength band, a second emission area EA2 that emits light of a second wavelength band lower than the first wavelength band, and a third emission area EA3 that emits light of a third wavelength band lower than the second wavelength band.

For example, the first wavelength band may be about 600 nm to about 750 nm, and the light of the first wavelength band may be red. The second wavelength band is about 480 nm to about 560 nm, and light of the second wavelength band may be green. The third wavelength band is about 370 nm to about 460 nm, and light of the third wavelength band may be blue.

Accordingly, a unit pixel PX that displays white light may be provided by one or more first emission areas EA1, one or more second emission areas EA2, and one or more third emission areas EA3 that are adjacent to each other among the emission areas EA.

According to an embodiment, the first emission areas EA1 and the third emission areas EA3 may be arranged alternately in a first direction DR1.

The second emission areas EA2 may be arranged side by side in the first direction DR1.

A row in which the first emission area EA1 and the third emission area EA3 are alternately arranged and a row in which the second emission areas EA2 are arranged may be alternately arranged in a second direction DR2.

According to an embodiment, the second emission area EA2 may be adjacent to a portion of the first emission area EA1, a portion of the third emission area EA3, and the non-emission area NEA between the first emission area EA1 and the third emission area EA3 in the second direction DR2.

According to an embodiment, the interval between the second emission areas EA2 adjacent in the first direction DR1 may be greater than the interval between the first emission area EA1 and the third emission area EA3 adjacent in the first direction DR1.

In this case, each of some of the spacers 400 arranged in the display area DA may overlap the non-emission area NEA between the second emitting areas EA2 adjacent in the first direction DR1.

According to an embodiment, the third emission area EA3 may be disposed to have a smaller width than the first emission area EA1 and the second emission area EA2. The first emission area EA1 may have a smaller width than the second emission area EA2.

Each of the emission areas EA may be disposed in one shape among a rectangle, a triangle, a rhombus, a square, a trapezoid, a circle, and an ellipse.

The circuit layer 120 of the first substrate 100 may include the light emitting pixel drivers EPD arranged side by side with each other.

The light emitting pixel drivers EPD may correspond to the emission areas EA, respectively.

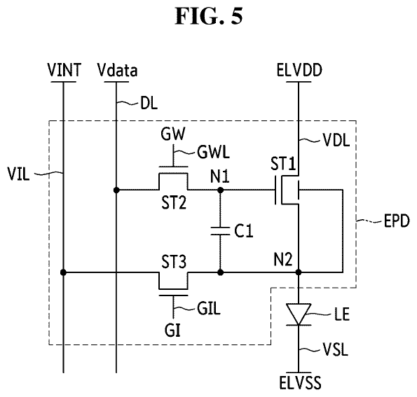

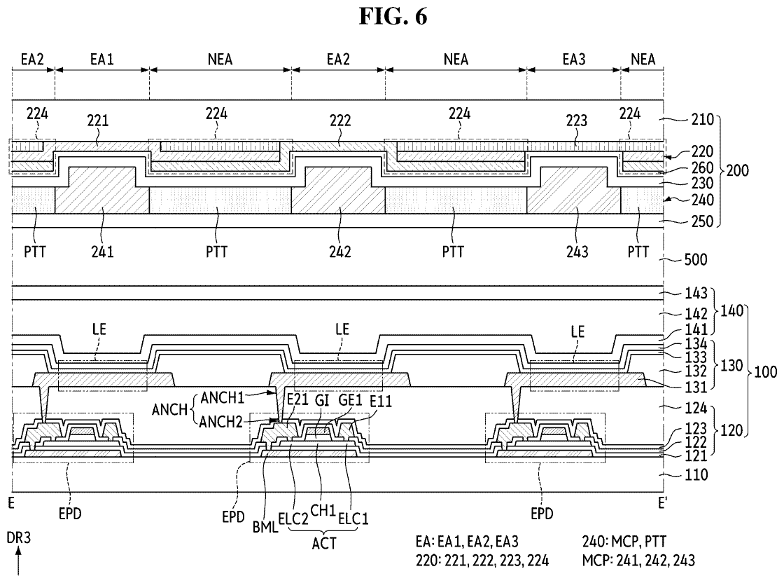

That is, the light emitting pixel drivers EPD may be respectively electrically connected to light emitting elements LE (see FIGS. 5 and 6) of the element layer 130 (see FIG. 2) disposed in the emission areas EA.

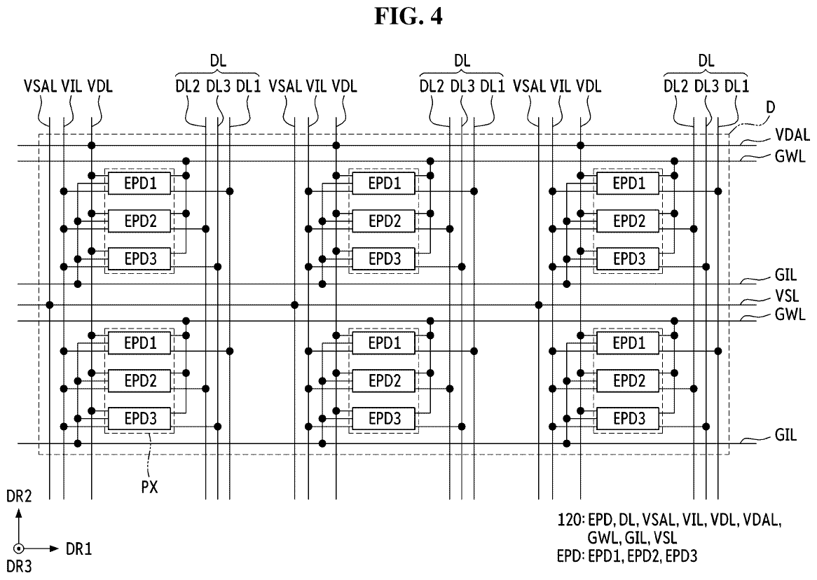

FIG. 4 is a block diagram illustrating the circuit layer of part D illustrated in FIG. 3.

Referring to FIG. 4, the circuit layer 120 may include the light emitting pixel drivers EPD, and lines VDL, DL, VIL, GWL, and GIL electrically connected to the light emitting pixel drivers EPD.

The lines VDL, DL, VIL, GWL, and GIL may transmit voltages or power and signals to each of the light emitting pixel drivers EPD.

For example, the circuit layer 120 may further include a scan write line GWL that transmits a scan write signal GW (see FIG. 5) to the light emitting pixel drivers EPD, a scan initialization line GIL that transmits a scan initialization signal GI (see FIG. 5) to the light emitting pixel drivers EPD, a data line DL that transmits a data signal Vdata (see FIG. 5) to the light emitting pixel drivers EPD, an initialization voltage line VIL that transmits an initialization voltage VINT (see FIG. 5) to the light emitting pixel drivers EPD, a first power line VDL that transmits a first power ELVDD (see FIG. 5) to the light emitting pixel drivers EPD, and a second power line VSL that transmits a second power ELVSS (see FIG. 5) to the light emitting elements LE (see FIG. 5).

The circuit layer 120 may further include a first power additional line VDAL for reducing the resistance of the first power line VDL, and a second power additional line VSAL for reducing the resistance of the second power line VSL.

The first power additional line VDAL may extend in a direction intersecting the first power line VDL, and may be electrically connected to the first power line VDL.

The second power additional line VSAL may extend in a direction intersecting the second power line VSL, and may be electrically connected to the second power line VSL.

The light emitting pixel drivers EPD may include a first light emitting pixel driver EPD1 electrically connected to the light emitting element LE (see FIG. 5) of the first emission area EA1 (see FIG. 3), a second light emitting pixel driver EPD2 electrically connected to the light emitting element LE (see FIG. 5) of the second emission area EA2 (see FIG. 3), and a third light emitting pixel driver EPD3 electrically connected to the light emitting element LE (see FIG. 5) of the third emission area EA3 (see FIG. 3).

The data lines DL may include a first data line DL1 that transmits the data signal Vdata (see FIG. 5) of the first light emitting pixel driver EPD1, a second data line DL2 that transmits the data signal Vdata (see FIG. 5) of the second light emitting pixel driver EPD2, and a third data line DL3 that transmits the data signal Vdata (see FIG. 5) of the third light emitting pixel driver EPD3.

FIG. 5 is an equivalent circuit diagram illustrating the light emitting pixel driver of FIG. 4.

Referring to FIG. 5, the light emitting pixel driver EPD may be electrically connected between a first power source ELVDD and the light emitting element LE, and the light emitting element LE may be electrically connected between the light emitting pixel driver EPD and a second power source ELVSS.

The light emitting element LE may be an organic light emitting diode (OLED) having an organic light emitting layer, a quantum dot light emitting diode (LED) including a quantum dot light emitting layer, a micro LED, or an inorganic LED having an inorganic semiconductor.

The second power source ELVSS may be at a voltage level lower than that of the first power source ELVDD.

That is, a first light emitting electrode of the light emitting element LE may be electrically connected to the light emitting pixel driver EPD, and a second light emitting electrode of the light emitting element LE may be electrically connected to the second power source ELVSS.

According to an embodiment, the light emitting elements LE of the element layer 130 (see FIG. 2) may emit light of a fourth wavelength band that is equal to or less than the third wavelength band. That is, the fourth wavelength band may be the same as the third wavelength band or lower than the third wavelength band.

The light emitting pixel driver EPD may include a first transistor ST1 that generates a driving current of the light emitting element LE, and one or more capacitors C1 and one or more transistors ST2 and ST3 electrically connected to the first transistor ST1.

The first transistor ST1 may be electrically connected between the first power line VDL and the light emitting element LE.

The first transistor electrode of the first transistor ST1 may be electrically connected to the first power line VDL.

The second transistor electrode of the first transistor ST1 may be electrically connected to a second node N2 and the first light emitting electrode of the light emitting element LE.

The first gate electrode of the first transistor ST1 may be electrically connected to a first node N1 and the second transistor ST2.

The second gate electrode of the first transistor ST1 may be electrically connected to the second node N2.

The second transistor ST2 may be electrically connected between the data line DL and the first node N1.

The gate electrode of the second transistor ST2 may be electrically connected to the scan write line GWL. That is, the second transistor ST2 may be turned on by the scan write signal of the scan write line GWL.

When the second transistor ST2 is turned on, the data signal Vdata of the data line DL may be transmitted to the first node N1.

Due to the data signal Vdata transmitted to the first node N1, a voltage difference (i.e., a gate-source voltage difference) between the gate electrode of the first transistor ST1 and the first transistor electrode of the first transistor ST1 becomes a difference voltage between the first power source ELVDD and the data signal Vdata, and thus may become greater than the threshold voltage of the first transistor ST1. Therefore, by turning on the first transistor ST1, a source-drain current of a magnitude corresponding to the data signal Vdata may be generated between the first transistor electrode and the second transistor electrode of the first transistor ST1. Further, the source-drain current of the first transistor ST1 may be supplied as a driving current to the light emitting element LE.

Accordingly, the driving current of the magnitude corresponding to the data signal Vdata is supplied to the light emitting element LE and, thus, the light emitting element LE may emit light with a luminance corresponding to the data signal Vdata.

The first capacitor C1 may be electrically connected between the first node N1 and the second node N2.

The first capacitor C1 may be charged by the data signal Vdata transmitted to the first node N1 through the turned-on second transistor ST2.

Hence, the potential of the first node N1 may be maintained for a predetermined period of time due to the voltage charged in the first capacitor C1.

The third transistor ST3 may be electrically connected between the initialization voltage line VIL and the second node N2.

The gate electrode of the third transistor ST3 may be electrically connected to the scan initialization line GIL. That is, the third transistor ST3 may be turned on by the scan initialization signal GI of the scan initialization line GIL.

When the third transistor ST3 is turned on, the potential of the second node N2, i.e., the potential of the first light emitting electrode of the light emitting element LE, may be initialized to the initialization voltage VINT of the initialization voltage line VIL.

As illustrated in FIG. 5, according to an embodiment, each of the first, second, and third transistors ST1, ST2, and ST3 may be an N-type MOSFET. However, this is an example, and at least one of the first, second, and third transistors ST1, ST2, and ST3 may be a P-type MOSFET.

FIG. 6 is a cross-sectional view taken along line E-E′ of FIG. 3.

Referring to FIG. 6, the display device 10 may include the first substrate 100 and the second substrate 200 that face each other, and the filling layer 500 that fills the space between the first substrate 100 and the second substrate 200.

The first substrate 100 may include the first support substrate 110, the circuit layer 120 disposed on the first support substrate 110, the element layer 130 including the light emitting elements LE disposed in the emission areas EA on the circuit layer 120, and the encapsulation layer 140 covering the element layer 130.

The first support substrate 110 may include the display area DA (see FIG. 1) and the non-display area NDA (see FIG. 1).

The display area DA may include the emission areas EA1, EA2, and EA3 (EA of FIG. 3) arranged side by side and the non-emission area NEA between the emission areas EA1, EA2, and EA3 (EA of FIG. 3).

The circuit layer 120 may include a buffer layer 121 disposed on the first support substrate 110, a first interlayer insulating layer 122 disposed on the buffer layer 121, a second interlayer insulating layer 123 disposed on the first interlayer insulating layer 122, and a planarization layer 124 disposed on the second interlayer insulating layer 123.

Each of the buffer layer 121, the first interlayer insulating layer 122, and the second interlayer insulating layer 123 may include an inorganic insulating material.

The planarization layer 124 may contain an organic insulating material.

The circuit layer 120 may include the light emitting pixel drivers EPD that transmit a driving current to the light emitting elements LE.

Each of the light emitting pixel drivers EPD may include two or more transistors ST1, ST2, and ST3 (see FIG. 6) and may be electrically connected to one or more lines DL, VDL, VIL, GWL, and GIL (see FIG. 5).

The first transistor ST1 of each of the light emitting pixel drivers EPD may include an active layer ACT disposed on the buffer layer 121, a gate electrode GE disposed on a gate insulating layer GI covering a channel portion CH1 of the active layer ACT, and a first transistor electrode E1 and a second transistor electrode E2 disposed on the first interlayer insulating layer 122 covering the active layer ACT and the gate electrode GE1.

At least the channel portion CH1 of the active layer ACT may overlap a light blocking layer BML on the first support substrate 110.

The buffer layer 121 may cover the light blocking layer BML.

The active layer ACT may include the channel portion CH1, a first transistor electrode portion ELC1 connected to one side of the channel portion CH1, and a second transistor electrode portion ELC2 connected to the other side of the channel portion CH1.

The first transistor electrode E1 may be electrically connected to the first transistor electrode portion ELC1 of the active layer ACT through a hole penetrating the first interlayer insulating layer 122.

The second transistor electrode E2 may be electrically connected to the second transistor electrode portion ELC2 of the active layer ACT through a hole penetrating the first interlayer insulating layer 122.

The second transistor electrode E2 may be electrically connected to the light blocking layer BML through a hole penetrating the first interlayer insulating layer 122 and the buffer layer 121.

The top surface of the channel portion CH1 may face the gate electrode GE, and the rear surface of the channel portion CH1 may face the light blocking layer BML electrically connected to the second transistor electrode E2.

Accordingly, based on the same potential of the light blocking layer BML as the second transistor electrode E2, a portion of the active layer ACT adjacent to the light blocking layer BML may be activated relatively weakly compared to another portion of the active layer ACT adjacent to the gate electrode GE.

The second interlayer insulating layer 123 may cover the first interlayer insulating layer 122, the first transistor electrode E1, and the second transistor electrode E2.

The planarization layer 124 may cover the second interlayer insulating layer 123 and may include an organic insulating material.

The element layer 130 may be disposed on the planarization layer 124 of the circuit layer 120.

The element layer 130 includes the light emitting elements LE disposed in the emission areas EA. The light emitting elements LE may emit light of the fourth wavelength band.

Each of the light emitting elements LE may have a structure in which a light emitting layer 133 is disposed between a first light emitting electrode 131 and a second light emitting electrode 134 facing each other.

That is, the element layer 130 may include the first light emitting electrodes 131 disposed in the emission areas EA on the circuit layer 120, a pixel defining layer 132 disposed in the non-emission area NEA on the circuit layer 120 and covering an edge of the first light emitting electrodes 131, the light emitting layer 133 disposed on the first light emitting electrodes 131, and the second light emitting electrode 134 disposed on the light emitting layer 133.

According to an embodiment, the light emitting layer 133 may be further disposed on the pixel defining layer 132 in the non-emission area NEA.

Alternatively, the light emitting layers 133 may be disposed in the emission areas EA, respectively and may be spaced apart from each other.

The first light emitting electrodes 131 may be electrically connected to the light emitting pixel drivers EPD through an anode connection hole ANCH.

That is, the first light emitting electrode 131 may be electrically connected to the second transistor electrode E2 of the first transistor ST1 of the light emitting pixel driver EPD through the anode connection hole ANCH.

The anode connection hole ANCH may penetrate the planarization layer 124 and the second interlayer insulating layer 123.

The pixel defining layer 132 may include an organic insulating material.

The light emitting layer 133 may include an organic light emitting material.

The second light emitting electrode 134 may be disposed in the display area DA including the emission areas EA1, EA2, and EA3 (EA of FIG. 3) and the non-emission area NEA.

The encapsulation layer 140 may include the first encapsulation layer 141 disposed on the element layer 130 and containing an inorganic insulating material, the second encapsulation layer 142 disposed on the first encapsulation layer 141 and containing an organic insulating material, and the third encapsulation layer 143 disposed on the second encapsulation layer 142 and containing an inorganic insulating material.

The encapsulation layer 140 may reduce defects in the circuit layer 120 or the element layer 130 due to foreign matters, and may delay or prevent defects in which oxygen or moisture permeates into the circuit layer 120 or the element layer 130.

According to an embodiment, the second substrate 200 may include the color filter layer 220 disposed on the second support substrate 210, the filter capping layer 230 covering the color filter layer 220, the color conversion layer 240 disposed on the filter capping layer 230, and the color conversion capping layer 250 covering the color conversion layer 240.

The second support substrate 210 may include the display area DA (see FIG. 1) and the non-display area NDA (see FIG. 1).

The second substrate 200 may further include a low refractive layer 260 disposed between the color filter layer 220 and the color conversion layer 240. For example, the low refractive layer 260 may be disposed on the color filter layer 220, and the filter capping layer 230 may be disposed on the low refractive layer 260.

In a direction in which light of the display device 10 is emitted (i.e., a third direction DR3), the low refractive layer 260 may be disposed on the color conversion layer 240, the color filter layer 220 may be disposed on the low refractive layer 260, and the second support substrate 210 may be disposed on the color filter layer 220. Accordingly, the light emitted from the light emitting elements LE of the element layer 130 may pass through the color conversion layer 240, the low refractive layer 260, the color filter layer 220, and the second support substrate 210 and be emitted to the outside.

The color conversion layer 240 may include main conversion portions MCP respectively overlapping the emission areas EA arranged in the display area DA, and a partition wall PTT disposed between the main conversion portions MCP.

The main conversion portions MCP may include a first color conversion portion 241 overlapping the first emission area EA1, a second color conversion portion 242 overlapping the second emission area EA2, and a light transmitting portion 243 overlapping the third emission area EA3.

Each of the first color conversion portion 241 and the second color conversion portion 242 may convert light of the fourth wavelength band emitted from the light emitting elements LE into light of a different wavelength band.

The first color conversion portion 241 may convert light emitted from the light emitting element LE of the first emission area EA1 from the fourth wavelength band to the first wavelength band.

The second color conversion portion 242 may convert light emitted from the light emitting element LE of the second emission area EA2 from the fourth wavelength band to the second wavelength band.

The light transmitting portion 243 may transmit and scatter light emitted from the light emitting element LE of the third emission area EA3.

The first color conversion portion 241 may be a cured product of a first ink material including a base resin and first color conversion particles dispersed in the base resin. The first color conversion particles may convert light of the fourth wavelength band into light of the first wavelength band.

The second color conversion portion 242 may be a cured product of a second ink material including a base resin and second color conversion particles dispersed in the base resin. The second color conversion particles may convert light of the fourth wavelength band into light of the second wavelength band.

Each of the first color conversion portion 241 and the second color conversion portion 242 may further include scattering particles dispersed in the base resin.

Each of the first color conversion particle and the second color conversion particle may be at least one of a quantum dot, a quantum rod, and a phosphor.

The quantum dot may be any one selected from group IV nanocrystals, group II-VI compound nanocrystals, group III-V compound nanocrystals, group IV-VI nanocrystals, and combinations thereof.

The first color conversion portion 241, the second color conversion portion 242, and the light transmitting portion 243 may include the same base resin, or may include different base resins.

The light transmitting portion 243 may include a base resin and scattering particles dispersed in the base resin.

The scattering particles may be metal oxide particles or organic particles.

The metal oxide particles may be at least one of titanium oxide (TiO₂), zirconium oxide (ZrO₂), aluminum oxide (Al₂O₃), indium oxide (In₂O₃), zinc oxide (ZnO), or tin oxide (SnO₂).

The organic particles may be acrylic resin or urethane resin.

The partition wall PTT may overlap at least a portion of the non-emission area NEA and be disposed among the first color conversion portion 241, the second color conversion portion 242, and the light transmitting portion 243.

The partition wall PTT may include a light-absorbing or light-blocking organic material.

The color conversion layer 240 may be sealed with a bonding structure between the filter capping layer 230 and the color conversion capping layer 250. Accordingly, the permeation of oxygen or moisture through the color conversion layer 240 may be reduced or delayed.

The color filter layer 220 may selectively transmit light from each of the emission areas EA emitted from the color conversion layer 240 in each of the emission areas EA.

The color filter layer 220 may include a first filter portion 221 that is disposed in the first emission area EA1 and transmits light of the first wavelength band, a second filter portion 222 that is disposed in the second emission area EA2 and transmits light of the second wavelength band, a third filter portion 223 that is disposed in the third emission area EA3 and transmits light of the third wavelength band, and a light blocking portion 224 that is disposed in the non-emission area NEA and the non-display area NDA (see FIG. 1) and blocks light.

Each of the first filter portion 221, the second filter portion 222, and the third filter portion 223 may include a colorant such as, for example, a dye or pigment. The colorant may be a material that absorbs light of the wavelength bands other than a predetermined wavelength band.

That is, the first filter portion 221 may include a colorant that absorbs light of the remaining wavelength bands excluding the first wavelength band among the light transmitted through the color conversion layer 240, and thus may transmit light in the first wavelength band.

The second filter portion 222 may include a colorant that absorbs light of the remaining wavelength bands excluding the second wavelength band among the light transmitted through the color conversion layer 240, and thus may transmit light of the second wavelength band.

The third filter portion 223 may include a colorant that absorbs light of the remaining wavelength bands excluding the third wavelength band among the light transmitted through the color conversion layer 240, and thus may transmit light of the third wavelength band.

The light blocking portion 224 may have a structure in which two or more filter portions among the first filter portion 221, the second filter portion 222, and the third filter portion 223 are stacked.

Alternatively, the light blocking portion 224 may include a material that absorbs light, such as, for example, a black matrix material.

The low refractive layer 260 may overlap the emission areas EA of the display area DA.

The low refractive layer 260 may include hollow silica particles dispersed in a transparent organic material.

Accordingly, the low refractive layer 260 may have a refractive index equal to or less than about 1.5 and greater than about 1.0. For example, the low refractive layer 260 may have a refractive index equal to or greater than about 1.1 and equal to or less than 1.4.

Due to the low refractive layer 260, the light emission efficiency of the second substrate 200 may be improved, such that the luminance and display quality of the display device 10 may be improved.

The filling layer 500 may fill the space between the first substrate 100 and the second substrate 200 separated by the spacers 400 (see FIG. 2).

The filling layer 500 may be disposed between the encapsulation layer 140 of the first substrate 100 and the color conversion capping layer 250 of the second substrate 200.

The filling layer 500 may include an organic material having a light transmitting property and an adhesive property.

For example, the filling layer 500 may include a silicon-based organic material or an epoxy-based organic material.

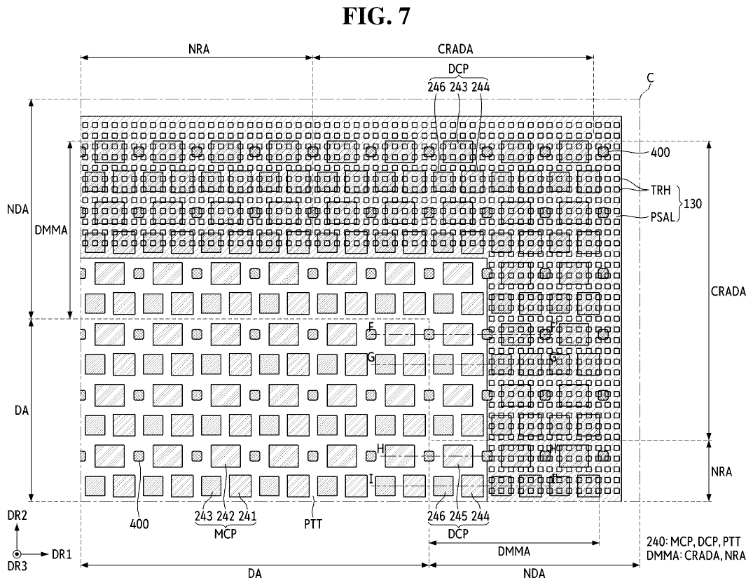

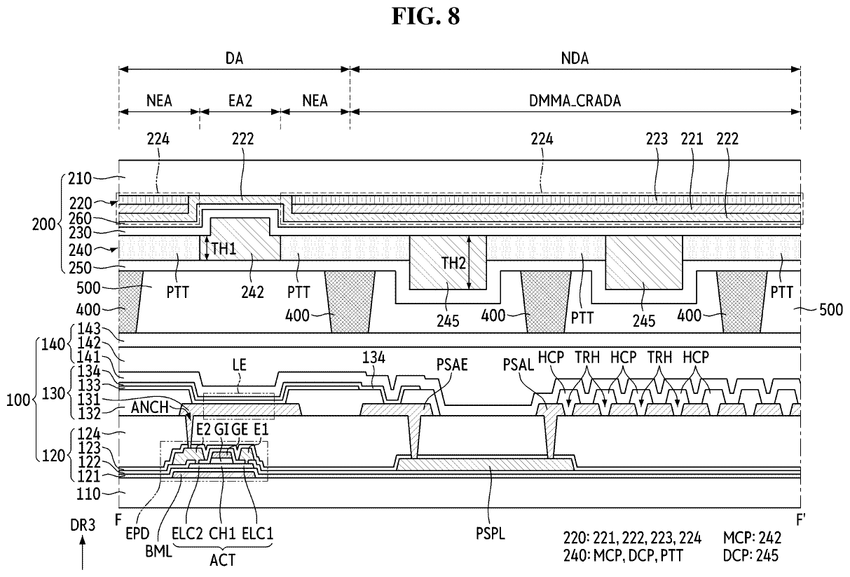

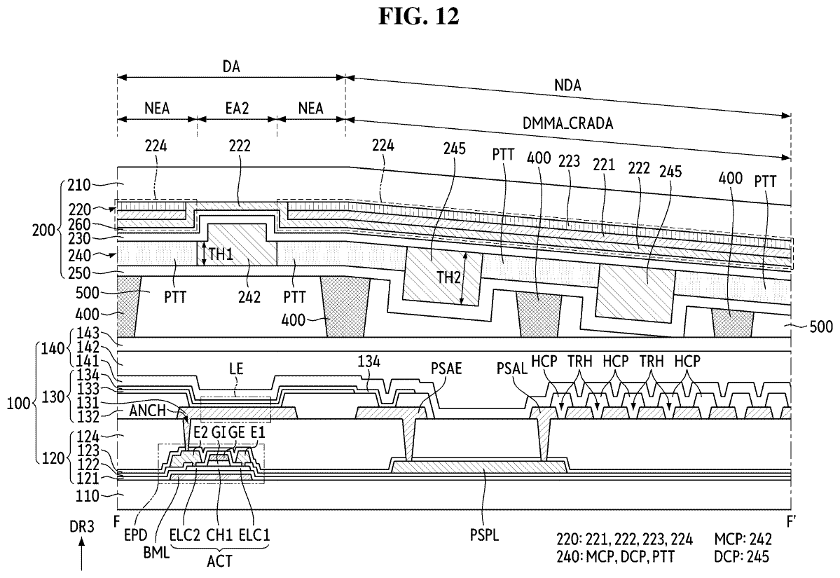

FIG. 7 is a schematic diagram illustrating a color conversion layer, spacers, and a power supply auxiliary line of part C illustrated in FIG. 1. FIGS. 8, 9, 10 and 11 are cross-sectional views taken along lines F-F′, G-G′, H-H′ and I-I′ of FIG. 7 according to an embodiment. FIG. 12 is a cross-sectional view taken along line F-F′ of FIG. 7 when a pressure for bonding the first substrate and the second substrate is concentrated.

As illustrated in FIG. 7, according to an embodiment, the non-display area NDA may include a dummy area DMMA that is a part of the non-display area NDA in contact with the display area DA.

The dummy area DMMA may include corner adjacent areas CRADA adjacent to the corners CRN (see FIG. 1) of the display device 10, and a general dummy area NRA that is a remaining portion of the dummy area DMMA excluding the corner adjacent areas CRADA.

That is, referring to FIG. 1 and FIG. 7, when one surface of the display device 10 is a quadrilateral including four corners CRN, each of the first support substrate 110 (see FIG. 6) and the second support substrate 210 (see FIG. 6) may be a quadrilateral including the display area DA, the non-display area NDA, and four corners CRN.

As illustrated in FIG. 1, each of the four corners CRN may be a portion at which edges extending in different directions meet. The four corners CRN may be disposed at the upper right, upper left, lower right, and lower left.

As illustrated in FIG. 7, the dummy area DMMA may include the corner adjacent area CRADA adjacent to the upper right corner CRN of the display device 10 of FIG. 1.

In some aspects, the dummy area DMMA may include the corner adjacent areas CRADA respectively adjacent to the upper left corner CRN, the lower right corner CRN, and the lower left corner CRN of the display device 10 of FIG. 1.

According to an embodiment, the color conversion layer 240 of the second substrate 200 (see FIG. 2) may include the main conversion portions MCP respectively overlapping the emission areas EA (see FIG. 3) arranged in the display area DA, the dummy conversion portions DCP arranged side by side with each other in the dummy area DMMA that is a portion of the non-display area NDA in contact with the display area DA, and the partition wall PTT disposed between the main conversion portions MCP and the dummy conversion portions DCP.

The main conversion portions MCP may include the first color conversion portion 241 overlapping the first emission area EA1 (see FIG. 3), the second color conversion portion 242 overlapping the second emission area EA2 (see FIG. 3), and the light transmitting portion 243 overlapping the third emission area EA3 (see FIG. 3).

The dummy conversion portions DCP may include a first dummy conversion portion 244 replacing the first color conversion portion 241, a second dummy conversion portion 245 replacing the second color conversion portion 242, and a third dummy conversion portion 246 replacing the light transmitting portion 243.

That is, the first dummy conversion portion 244 and the third dummy conversion portion 246 may be adjacent to the first color conversion portion 241 and the light transmitting portion 243 and may be alternately arranged with each other, in the first direction DR1.

The second dummy conversion portion 245 may be adjacent to the second color conversion portion 242 and may be alternately arranged side by side with each other, in the first direction DR1.

According to an embodiment, the first dummy conversion portion 244 may have the same width as the first color conversion portion 241, the second dummy conversion portion 245 may have the same width as the second color conversion portion 242, and the third dummy conversion portion 246 may have the same width as the light transmitting portion 243.

The partition wall PTT may overlap at least a portion of the non-emission area NEA (see FIG. 3) of the display area DA and may overlap a portion between the dummy conversion portions DCP in the dummy area DMMA.

The filling layer 500 may overlap the partition wall PTT.

For example, the filling layer 500 may overlap the partition wall PTT between the adjacent two among the second color conversion portions 242 and the second dummy conversion portions 245. That is, the partition wall PTT may be adjacent to the second color conversion portion 242 or the second dummy conversion portion 245 in the first direction DR1.

According to an embodiment, the element layer 130 may include a power supply auxiliary line PSAL disposed in the non-display area NDA and overlapping the dummy conversion portions DCP, and through holes TRH formed in the power supply auxiliary line PSAL and arranged side by side with each other.

The through holes TRH may penetrate the power supply auxiliary line PSAL, and gas generated in the organic insulating material between the power supply auxiliary line PSAL and the first support substrate 110 may be relatively easily discharged through the through holes TRH. Accordingly, a lifting defect of the power supply auxiliary line PSAL due to gas of the organic insulating material may be reduced.

According to an embodiment, at least one spacer 400 among the spacers 400 arranged in the non-display area NDA may be adjacent to or overlap at least one through hole TRH.

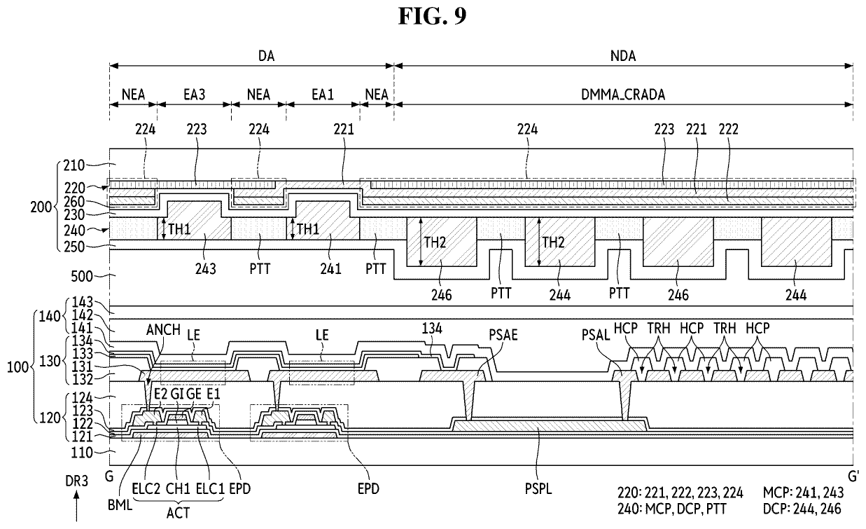

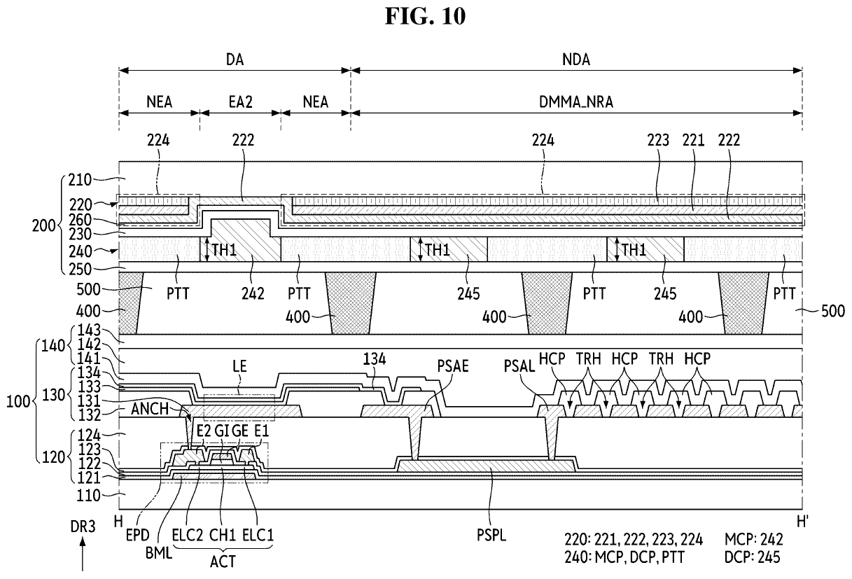

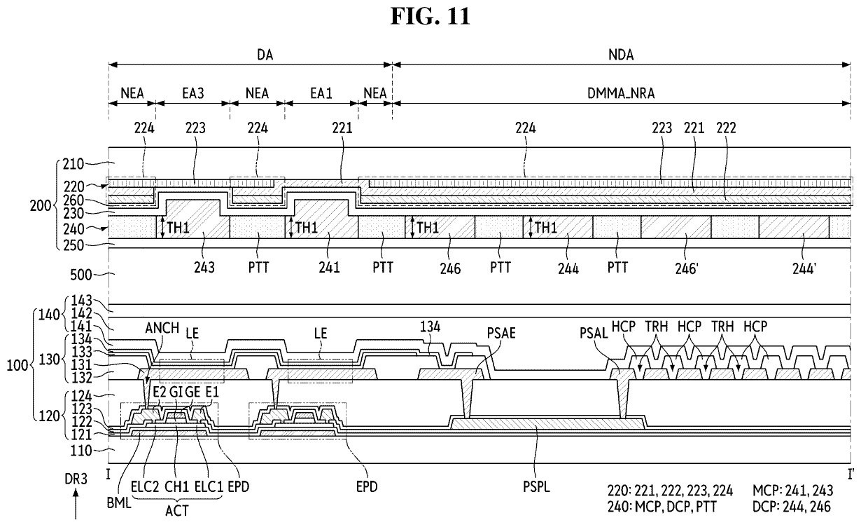

As illustrated in FIGS. 8, 9, 10, and 11, each of the main conversion portions MCP, which overlap the emission areas EA (see FIG. 7), EA2 (see FIGS. 8 and 10), and EA1 and EA3 (see FIGS. 9 and 11) of the display area DA, in the color conversion layer 240 of the second substrate 200 may have a first thickness TH1. For example, the minimum thickness of each of the main conversion portions MCP may be the first thickness TH1.

As illustrated in FIGS. 8 and 9, according to an embodiment, the color conversion layer 240 of the second substrate 200 includes the dummy conversion portions DCP, 245 (see FIG. 8), and 244 and 246 (see FIG. 9) arranged in the dummy area DMMA of the non-display area NDA.

In some aspects, according to an embodiment, each of some of the dummy conversion portions DCP, which are adjacent to the corners CRN (see FIG. 1) of the second substrate 200, among the dummy conversion portions DCP may have a second thickness TH2 greater than the first thickness TH1. That is, each of the dummy conversion portions DCP arranged in the corner adjacent area CRADA in the dummy area DMMA may have the second thickness TH2.

In this way, as illustrated in the diagram of FIG. 12, although the physical pressure for bonding the first substrate 100 and the second substrate 200 is relatively strongly applied to the non-display area NDA, especially to the corner adjacent area CRADA in the non-display area NDA, the physical pressure may be distributed by the dummy conversion portions DCP disposed with the second thickness TH2, such that the pressing defect of the spacers 400 may be reduced.

In some aspects, the defect in which the third encapsulation layer 143 that is in contact with the spacers 400 and includes an inorganic insulating material is cracked or damaged due to the pressing defect of the spacers 400 may be reduced. Accordingly, the defect in which oxygen or moisture permeates through the cracked or broken third encapsulation layer 143 may be prevented or reduced.

Accordingly, the display quality and lifespan of the display device 10 may be improved.

In some aspects, since the pressing defect of the spacers 400 may be prevented or reduced by the dummy conversion portions DCP disposed with the second thickness TH2, when the first substrate 100 and the second substrate 200 are bonded, the physical pressure applied to the corner adjacent area CRADA of the non-display area NDA may increase. Accordingly, the ease of the process of bonding between the first substrate 100 and the second substrate 200 may be improved.

As illustrated in FIGS. 10 and 11, according to an embodiment, each of some of the other remaining dummy conversion portions DCP arranged in the general dummy area NRA among the dummy conversion portions DCP may have the same first thickness TH1 as the main conversion portions MCP.

For example, the minimum thickness of each of some of the dummy conversion portions DCP arranged in the corner adjacent area CRADA may be the second thickness TH2.

As another example, the second thickness TH2 may be greater than the maximum thickness of each of the main conversion portions MCP.

In an embodiment, the difference between the first thickness TH1 and the second thickness TH2 may be about 0.5 μm or more.

When the difference between the first thickness TH1 and the second thickness TH2 is less than 0.5 μm, the stepped portions of the dummy conversion portions DCP disposed with the second thickness TH2 may be lower than the stepped portion of the spacer 400 pressed due to the concentrated pressure. Accordingly, the dummy conversion portions DCP disposed with the second thickness TH2 may have a minimal effect on distributing the pressure concentrated on some of the spacers 400.

For example, the difference between the first thickness TH1 and the second thickness TH2 may be less than or equal to the thickness of the spacers 400. In this way, the defect in which the dummy conversion portions DCP disposed with the second thickness TH2 protrude beyond the spacers 400 may be prevented.

As illustrated in FIGS. 8, 9, 10 and 11, according to an embodiment, the circuit layer 120 may include the light emitting pixel drivers EPD electrically connected to the light emitting elements LE of the emission areas EA (see FIG. 7), respectively, and power supply lines PSPL disposed in the non-display area NDA.

The power supply line PSPL may transmit the second power ELVSS, between the first power ELVDD (see FIG. 5) and the second power ELVSS (see FIG. 5) for generating a driving current of the light emitting elements LE. That is, the power supply line PSPL may be the second power line VSL (see FIG. 5) electrically connected to the second electrode 134 of the element layer 130.

The power supply line PSPL may be disposed on the first interlayer insulating layer 122 together with the first transistor electrode E1 and the second transistor electrode E2.

The power supply line PSPL may be covered with the second interlayer insulating layer 123 and the planarization layer 124.

The element layer 130 may include the first light emitting electrodes 131 disposed in the emission areas EA on the circuit layer 120, the pixel defining layer 132 disposed on the circuit layer 120, overlapping the non-emission area NEA between the emission areas EA, and covering an edge of each of the first light emitting electrodes 131, the light emitting layer 133 disposed on the first light emitting electrodes 131, the second light emitting electrode 134 disposed on the light emitting layer 133, the power supply auxiliary line PSAL disposed in the non-display area NDA on the circuit layer 120 and overlapping the dummy conversion portions DCP, the through holes TRH formed in the power supply auxiliary line PSAL and arranged side by side with each other, and hole cap portions HCP disposed in the same layer as the pixel defining layer 132, covering the through holes TRH, and spaced apart from each other.

Each of the light emitting elements LE of the element layer 130 may have a structure in which the light emitting layer 133 is sandwiched between the first light emitting electrode 131 and the second light emitting electrode 134.

The element layer 130 may further include the power supply auxiliary electrode PSAE disposed in the non-display area NDA on the circuit layer 120 and adjacent to the display area DA.

That is, the first light emitting electrodes 131, the power supply auxiliary line PSAL, and the power supply auxiliary electrode PSAE may be disposed in the same layer.

The power supply line PSPL may be electrically connected to the second light emitting electrode 134 and the power supply auxiliary line PSAL.

That is, the power supply auxiliary electrode PSAE may be electrically connected to the second light emitting electrode 134 and the power supply line PSPL. Accordingly, the second light emitting electrode 134 may be electrically connected to the power supply line PSPL through a power supply auxiliary electrode PSAE.

In some aspects, the power supply auxiliary line PSAL may be electrically connected to the power supply line PSPL through at least one connection hole penetrating the planarization layer 124 and the second interlayer insulating layer 123. Accordingly, the resistance of the power supply line PSPL may be lowered by electrical connection with the power supply auxiliary line PSAL, such that the voltage level of the second power source ELVSS (see FIG. 5) may be maintained relatively constant.

In this way, according to an embodiment, the power supply auxiliary line PSAL including the through holes TRH and the hole cap portions HCP covering the through holes TRH may be disposed in the non-display area NDA. Accordingly, at least one spacer 400 among the spacers 400 arranged in the non-display area NDA may overlap at least one of the hole cap portions HCP.

The hole cap portions HCP are disposed in an island shape to be spaced apart from each other in the same layer as the pixel defining layer 132, and the first encapsulation layer 141 covers the hole cap portions HCP and the power supply auxiliary line PSAL.

Accordingly, due to the stepped portion of the hole cap portions HCP, the portions of the second encapsulation layer 142 overlapping each of the hole cap portions HCP may have a relatively small thickness.

That is, the portions of the first encapsulation layer 141 overlapping each of the hole cap portions HCP may be spaced apart from the third encapsulation layer 143 by a relatively short interval.

Accordingly, not only the third encapsulation layer 143 in contact with the spacers 400, but also the portions of the first encapsulation layer 141 overlapping each of the hole cap portions HCP, may be relatively greatly affected by the pressing defect of the spacers 400.

However, according to an embodiment, the pressing defect of the spacers 400 may be reduced or prevented by some of the dummy conversion portions DCP disposed with the second thickness TH2. Accordingly, similarly to the third encapsulation layer 143, the defect in which the portions of the first encapsulation layer 141 overlapping each of the hole cap portions HCP are cracked or broken due to the pressing defect of the spacers 400 may be reduced or prevented.

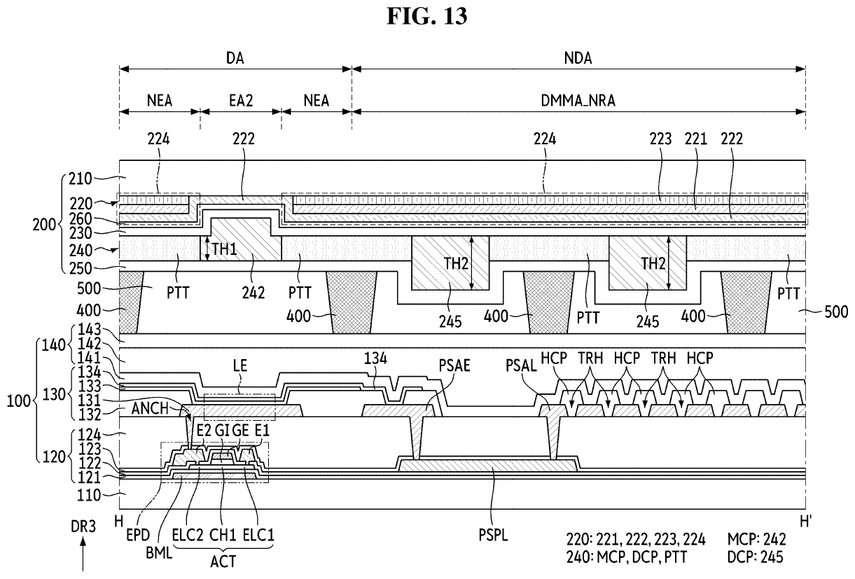

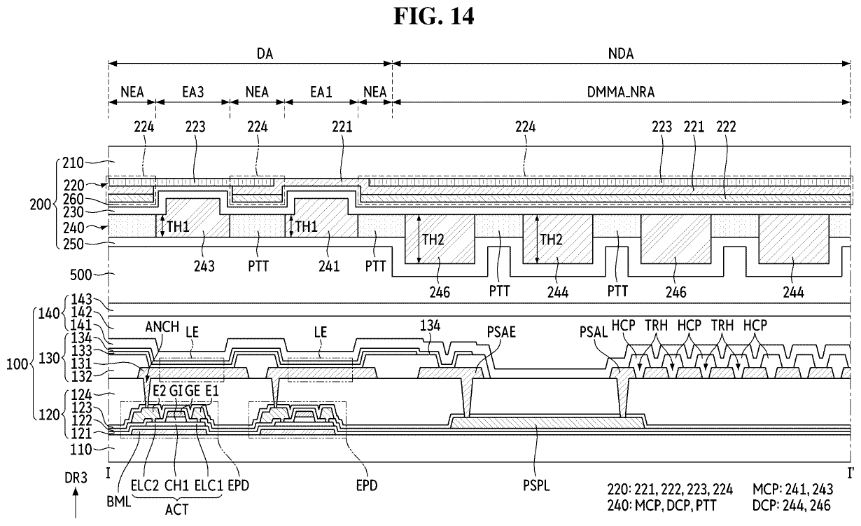

FIGS. 13 and 14 are cross-sectional views taken along lines H-H′ and I-I′ of FIG. 7 according to an embodiment.

The display device 10 of an embodiment illustrated in FIGS. 13 and 14 is substantially the same as the display device 10 of an embodiment illustrated in FIGS. 8, 9, 10, and 11, except that all of the dummy conversion portions DCP arranged in the dummy area DMMA of the non-display area NDA in the color conversion layer 240 of the second substrate 200 are disposed with the second thickness TH2, such that redundant description will be omitted below.

According to an embodiment of FIGS. 13 and 14, each of some of the other remaining dummy conversion portions DCP arranged in the general dummy area NRA among the dummy conversion portions DCP may have the second thickness TH2 rather than the first thickness TH1, similarly to some of the dummy conversion portions DCP arranged in the corner adjacent area CRADA.

In this way, although the physical pressure for bonding the first substrate 100 and the second substrate 200 is relatively strongly applied to the non-display area NDA overlapping the sealing layer 300, the physical pressure may be distributed by the dummy conversion portions DCP, such that the pressing defect of the spacers 400 may be entirely reduced in the non-display area NDA.

The defect in which the third encapsulation layer 143 in contact with the spacers 400 and the portions of the first encapsulation layer 141 overlapping the hole cap portions HCP are cracked or damaged due to the pressing defect of the spacers 400 may be entirely reduced in the non-display area NDA.

Accordingly, the defect in which oxygen or moisture permeates through the cracked or broken third encapsulation layer 143 or the first encapsulation layer 141 may be further prevented or reduced.

Accordingly, the display quality and lifespan of the display device 10 may be further improved.

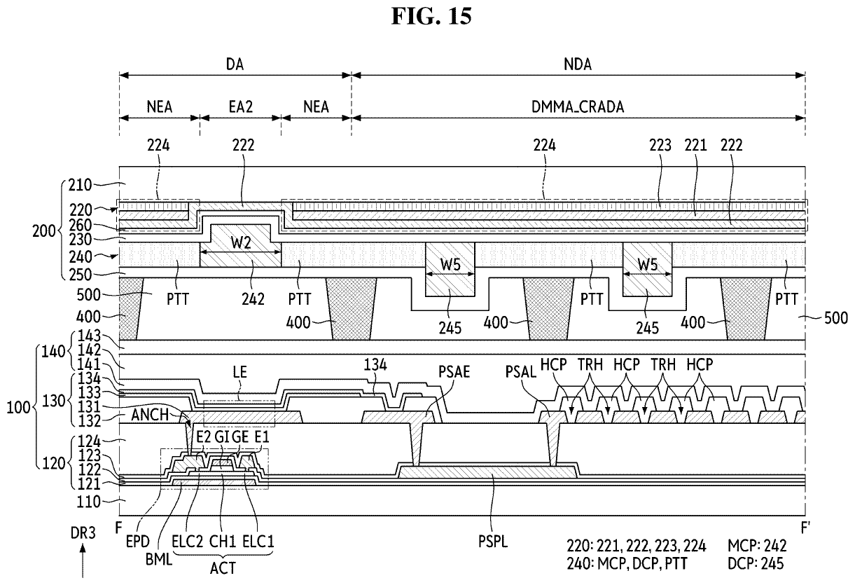

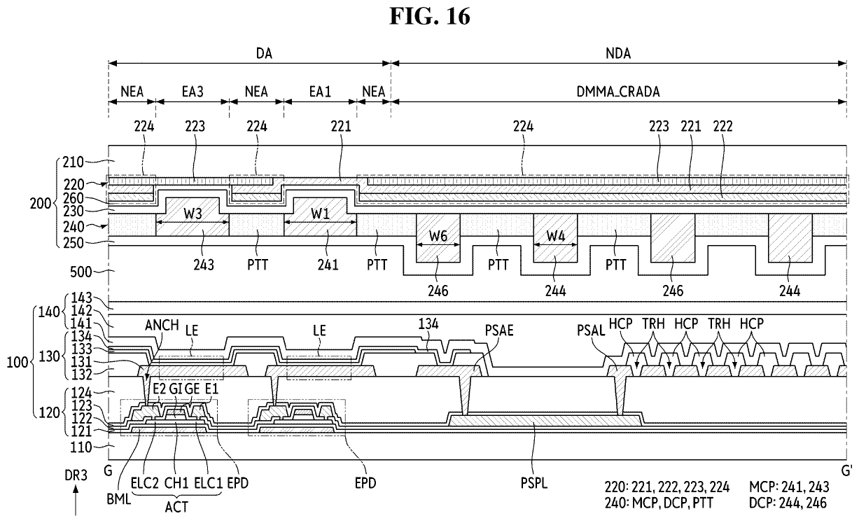

FIGS. 15 and 16 are cross-sectional views taken along lines F-F′ and G-G′ of FIG. 7 according to an embodiment.

The display device 10 of an embodiment illustrated in FIGS. 15 and 16 is substantially the same as the display device 10 of an embodiment illustrated in FIGS. 8, 9, 10, and 11, and the display device 10 of an embodiment illustrated in FIGS. 13 and 14, except that the dummy conversion portions DCP disposed with the second thickness TH2 in the color conversion layer 240 of the second substrate 200 are disposed with a smaller width than the main conversion portions MCP disposed with the first thickness TH1, such that redundant description will be omitted below.

As illustrated in FIGS. 15 and 16, according to an embodiment, each of the main conversion portions MCP of the color conversion layer 240 may have the first thickness TH1. Among the main conversion portions MCP, the first color conversion portion 241 overlapping the first emission area EA1 may have a first width W1, the second color conversion portion 242 overlapping the second emission area EA2 may have a second width W2, and the light transmitting portion 243 overlapping the third emission area EA3 may have a third width W3.

For example, as illustrated in FIG. 3, the second emission area EA2 may have a larger width than the first emission area EA1 and the third emission area EA3. The first emission area EA1 may have a larger width than the third emission area EA3.

In this case, as illustrated in FIG. 7, FIG. 15, and FIG. 16, the second width W2 of the second color conversion portion 242 overlapping the second emission area EA2 may be larger than the first width W1 of the first color conversion portion 241 overlapping the first emission area EA1 and the third width W3 of the light transmitting portion 243 overlapping the third emission area EA3. In some aspects, the first width W1 of the first color conversion portion 241 may be larger than the third width W3 of the light transmitting portion 243.

According to an embodiment of FIGS. 15 and 16, each of at least some dummy conversion portions DCP among the dummy conversion portions DCP arranged in the dummy area DMMA of the non-display area NDA may have the second thickness TH2 greater than the first thickness TH1.

Among the dummy conversion portions DCP disposed with the second thickness TH2, the first dummy conversion portion 244 replacing the first color conversion portion 241 may have a fourth width W4 smaller than the first width W1, the second dummy conversion portion 245 replacing the second color conversion portion 242 may have a fifth width W5 smaller than the second width W2, and the third dummy conversion portion 246 replacing the light transmitting portion 243 may have a sixth width W6 smaller than the third width W3.

In this way, the dummy conversion portions DCP having the second thickness TH2 may be formed even without changing the dropping amount of an ink material to form the main conversion portions MCP having the first thickness TH1.

Accordingly, the ease of the process of disposing the color conversion layer 240 may be improved.

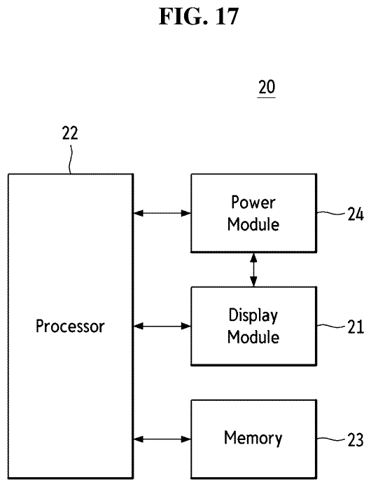

The display device 10 of each embodiment as described herein may be applied to various electronic devices 20 (see FIG. 17).

An electronic device 20 (see FIG. 17) according to an embodiment may include the display device 10 described herein.

In some aspects, the electronic device 20 (see FIG. 17) according to an embodiment may further include a module or device having other additional functions in addition to the display device 10.

FIG. 17 is a block diagram illustrating an electronic device according to an embodiment.

Referring to FIG. 17, the electronic device 20 according to an embodiment may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), or a controller.

Data information supportive of the operation of the processor 22 or display module 21 may be stored in the memory 23. In an example in which the processor 22 executes an application stored in the memory 23, an image data signal and/or an input control signal may be transmitted to the display module 21, and the display module 21 may process the provided signal and may output image information through a display screen.

The power module 24 may include a power supply module such as, for example, a power adapter or a battery device, and a power conversion module that converts power supplied by the power supply module to generate power for the operation of the electronic device 20.

At least one of the respective components of the electronic device 20 described herein may be included in the display device according to the embodiments described herein. In some aspects, some of the individual modules functionally included within one module may be included within the display device, and others may be provided separately from the display device. For example, the display device may include the display module 21, and the processor 22, the memory 23 and the power module 24 may be provided in the form of other devices within the electronic device 20 other than the display device.

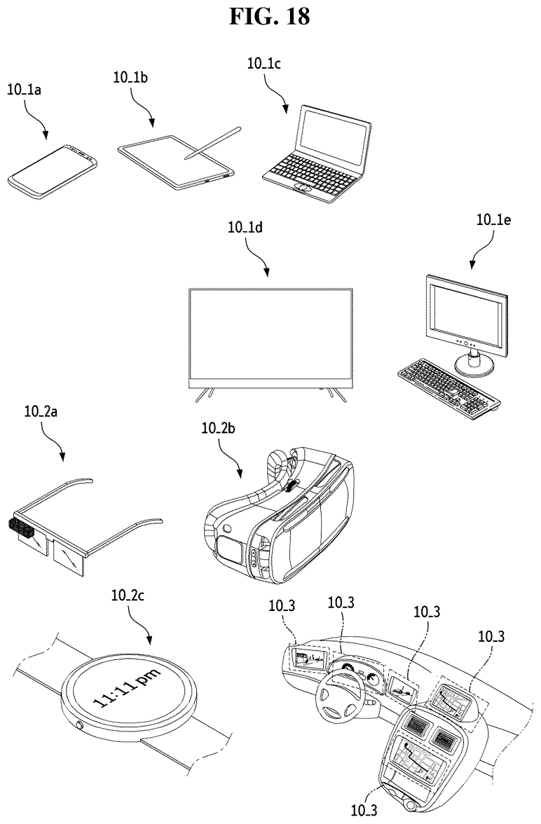

FIG. 18 is a schematic diagram of electronic devices according to embodiments.

Referring to FIG. 18, the electronic devices 20 (see FIG. 17) according to the embodiments may include not only an image display electronic device such as, for example, a smartphone 10_1a, a tablet PC 10_1b, a laptop 10_1c, a TV 10_1d, and a desk monitor 10_1e, but also a wearable electronic device such as, for example, smart glasses 10_2a, a head mounted display 10_2b, and a smart watch 10_2c, and a vehicle electronic device 10_3 such as, for example, a dashboard of a vehicle, a center fascia, a center information display (CID) of the dashboard, and a room mirror display.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a first substrate and a second substrate facing each other;
a sealing layer which bonds the first substrate and the second substrate; and
spacers supporting a gap between the first substrate and the second substrate,
wherein the first substrate comprises:
a first support substrate comprising:
a display area comprising emission areas arranged side by side with each other, and
a non-display area surrounding the display area; and
an element layer comprising light emitting elements disposed in the emission areas on the first support substrate, and
the second substrate comprises:
a second support substrate comprising the display area and the non-display area; and
a color conversion layer disposed on a surface of the second support substrate facing the first support substrate,
wherein the color conversion layer comprises:
main conversion portions respectively overlapping the emission areas and having a first thickness;
dummy conversion portions arranged side by side with each other in a partial area of the non-display area in contact with the display area; and
a partition wall disposed between the main conversion portions and the dummy conversion portions,
wherein each of at least some dummy conversion portions among the dummy conversion portions has a second thickness greater than the first thickness.

2. The display device of claim 1, wherein:
the element layer comprises:
a power supply auxiliary line disposed in the non-display area and overlapping the dummy conversion portions;
through holes formed in the power supply auxiliary line and arranged side by side with each other; and
hole cap portions covering the through holes and spaced apart from each other,
the spacers overlap the partition wall, and
at least one spacer, which overlaps the partition wall between the dummy conversion portions among the spacers, overlaps at least one of the hole cap portions.

3. The display device of claim 2, wherein:
the first substrate further comprises:
a circuit layer disposed on the first support substrate; and
an encapsulation layer covering the element layer,
wherein the element layer is disposed on the circuit layer,
the element layer comprises:
first light emitting electrodes disposed in the emission areas on the circuit layer;
a pixel defining layer which is disposed on the circuit layer, overlaps a non-emission area between the emission areas, and covers an edge of each of the first light emitting electrodes;
a light emitting layer disposed on the first light emitting electrodes; and
a second light emitting electrode disposed on the light emitting layer,
each of the light emitting elements has a structure in which the light emitting layer is sandwiched between a respective first light emitting electrode and the second light emitting electrode,
the power supply auxiliary line is disposed in a same layer as the first light emitting electrodes, and
the hole cap portions are disposed in a same layer as the pixel defining layer.

4. The display device of claim 3, wherein the encapsulation layer comprises:
a first encapsulation layer disposed on the second light emitting electrode and comprising an inorganic insulating material;
a second encapsulation layer disposed on the first encapsulation layer, overlapping the display area, and comprising an organic insulating material; and
a third encapsulation layer covering the second encapsulation layer and comprising the inorganic insulating material,
wherein the spacers are in contact with the third encapsulation layer.

5. The display device of claim 3, wherein the circuit layer comprises:
light emitting pixel drivers electrically connected to the first light emitting electrodes; and
a power supply line disposed in the non-display area,
wherein the power supply line is electrically connected to the second light emitting electrode and the power supply auxiliary line.

6. The display device of claim 2, wherein:
one or more dummy conversion portions among the dummy conversion portions are adjacent to corners of the second substrate and have the second thickness, and
one or more remaining dummy conversion portions among the dummy conversion portions have the first thickness.

7. The display device of claim 2, wherein the dummy conversion portions have the second thickness.

8. The display device of claim 2, wherein a difference between the first thickness and the second thickness is about 0.5 μm or more.

9. The display device of claim 2, wherein:
the emission areas comprise:
a first emission area which emits light of a first wavelength band;
a second emission area which emits light of a second wavelength band that is lower than the first wavelength band; and
a third emission area which emits light of a third wavelength band that is lower than the second wavelength band,
the light emitting elements emit light of a fourth wavelength band that is equal to or lower than the third wavelength band, and
the main conversion portions comprise:
a first color conversion portion which overlaps the first emission area and converts light of the fourth wavelength band into light of the first wavelength band;
a second color conversion portion which overlaps the second emission area and converts light of the fourth wavelength band into light of the second wavelength band; and
a light transmitting portion which overlaps the third emission area and transmits light of the fourth wavelength band.

10. The display device of claim 9, wherein:
among the at least some dummy conversion portions, a width of a first dummy conversion portion replacing the first color conversion portion is equal to a width of the first color conversion portion,
among the at least some dummy conversion portions, a width of a second dummy conversion portion replacing the second color conversion portion is equal to a width of the second color conversion portion, and
among the at least some dummy conversion portions, a width of a third dummy conversion portion replacing the light transmitting portion is equal to a width of the light transmitting portion.

11. The display device of claim 9, wherein:
among the at least some dummy conversion portions, a width of a first dummy conversion portion replacing the first color conversion portion is smaller than a width of the first color conversion portion,
among the at least some dummy conversion portions, a second dummy conversion portion replacing the second color conversion portion is smaller than a width of the second color conversion portion, and
among the at least some dummy conversion portions, a third dummy conversion portion replacing the light transmitting portion is smaller than a width of the light transmitting portion.

12. The display device of claim 9, wherein:
the second substrate further comprises:
a color filter layer disposed on a surface of the second support substrate; and
a filter capping layer covering the color filter layer,
the color conversion layer is disposed on the filter capping layer, and
the color filter layer comprises:
a first filter portion which overlaps the first emission area and transmits light of the first wavelength band;
a second filter portion which overlaps the second emission area and transmits light of the second wavelength band;
a third filter portion which overlaps the third emission area and transmits light of the third wavelength band; and
a light blocking portion disposed between the first filter portion, the second filter portion, and the third filter portion.

13. An electronic device comprising:
a display device displaying an image,
wherein the display device comprises:
a first substrate and a second substrate facing each other;
a sealing layer which bonds the first substrate and the second substrate; and
spacers supporting a gap between the first substrate and the second substrate,
wherein the first substrate comprises:
a first support substrate comprising:
a display area comprising emission areas arranged side by side with each other, and
a non-display area surrounding the display area; and
a circuit layer disposed on the first support substrate;
an element layer comprising light emitting elements disposed in the emission areas on the circuit layer, and
an encapsulation layer covering the element layer,
the second substrate comprises:
a second support substrate comprising the display area and the non-display area;
a color conversion layer disposed on a surface of the second support substrate facing the first support substrate;
a filter capping layer covering the color filter layer;
a color conversion layer disposed on the filter capping layer; and
a color conversion capping layer covering the color conversion layer,
wherein the color conversion layer comprises:
main conversion portions respectively overlapping the emission areas and having a first thickness;
dummy conversion portions arranged side by side with each other in a partial area of the non-display area in contact with the display area; and
a partition wall disposed between the main conversion portions and the dummy conversion portions,
wherein each of at least some dummy conversion portions among the dummy conversion portions has a second thickness greater than the first thickness.

14. The electronic device of claim 13, wherein:
the element layer comprises:
first light emitting electrodes disposed in the emission areas on the circuit layer;
a pixel defining layer which is disposed on the circuit layer, overlaps a non-emission area between the emission areas, and covers an edge of each of the first light emitting electrodes;
a light emitting layer disposed on the first light emitting electrodes;
a second light emitting electrode disposed on the light emitting layer;
a power supply auxiliary line disposed in the non-display area on the circuit layer and overlapping the dummy conversion portions;
through holes formed in the power supply auxiliary line and arranged side by side with each other; and
hole cap portions which are disposed in a same layer as the pixel defining layer, cover the through holes, and are spaced apart from each other,
each of the light emitting elements has a structure in which the light emitting layer is sandwiched between a respective first light emitting electrode and the second light emitting electrode,
the spacers overlap the partition wall, and
at least one spacer, which overlaps the partition wall between the dummy conversion portions among the spacers, overlaps at least one of the hole cap portions.

15. The electronic device of claim 14, wherein the encapsulation layer comprises:
a first encapsulation layer disposed on the second light emitting electrode and comprising an inorganic insulating material;
a second encapsulation layer disposed on the first encapsulation layer, overlapping the display area, and comprising an organic insulating material; and
a third encapsulation layer covering the second encapsulation layer and comprising the inorganic insulating material,
wherein the spacers are in contact with the third encapsulation layer.

16. The electronic device of claim 13, wherein:
one or more dummy conversion portions among the dummy conversion portions are adjacent to corners of the second substrate and have the second thickness, and
one or more remaining dummy conversion portions among the dummy conversion portions have the first thickness.

17. The electronic device of claim 13, wherein the dummy conversion portions have the second thickness.

18. The electronic device of claim 13, wherein:
the emission areas comprise:
a first emission area which emits light of a first wavelength band;
a second emission area which emits light of a second wavelength band that is lower than the first wavelength band; and
a third emission area which emits light of a third wavelength band that is lower than the second wavelength band,
the light emitting elements emit light of a fourth wavelength band that is equal to or lower than the third wavelength band, and
the main conversion portions comprise:
a first color conversion portion which overlaps the first emission area and converts light of the fourth wavelength band into light of the first wavelength band;
a second color conversion portion which overlaps the second emission area and converts light of the fourth wavelength band into light of the second wavelength band; and
a light transmitting portion which overlaps the third emission area and transmits light of the fourth wavelength band.

19. The electronic device of claim 18, wherein:
among the at least some dummy conversion portions, a width of a first dummy conversion portion replacing the first color conversion portion is equal to a width of the first color conversion portion,
among the at least some dummy conversion portions, a width of a second dummy conversion portion replacing the second color conversion portion is equal to a width of the second color conversion portion, and
among the at least some dummy conversion portions, a width of a third dummy conversion portion replacing the light transmitting portion is equal to a width of the light transmitting portion.

20. The electronic device of claim 18, wherein:
among the at least some dummy conversion portions, a width of a first dummy conversion portion replacing the first color conversion portion is smaller than a width of the first color conversion portion,
among the at least some dummy conversion portions, a width of a second dummy conversion portion replacing the second color conversion portion is smaller than a width of the second color conversion portion, and
among the at least some dummy conversion portions, a width of a third dummy conversion portion replacing the light transmitting portion is smaller than a width of the light transmitting portion.
